(19) United States
(12) Patent Application Publication
(10) Pub. No.: US 2015/0076582 A1
(43) Pub. Date: Mar. 19, 2015

(54) TRANSISTOR AND FABRICATION METHOD THEREOF

(71) Applicant: National Tsing Hua University, Hsinchu (TW)

(72) Inventors: Chrong-Jung Lin, Hsinchu (TW); Ya-Chin King, Taipei (TW)

(73) Assignee: National Tsing Hua University, Hsinchu (TW)

(21) Appl. No.: 14/194,875

(22) Filed: Mar. 3, 2014

(30) Foreign Application Priority Data
Sep. 17, 2013 (TW) 102133585

(51) Int. Cl. H01L 29/78; H01L 29/66; H01L 29/788

(52) U.S. Cl. CPC H01L 29/7831; H01L 29/788; H01L 29/66484; H01L 29/66825
USPC 257/315; 438/266

(57) ABSTRACT

A transistor is provided. The transistor includes a substrate, a gate electrode formed on the substrate, and multiple floating gates formed on the substrate. A fixed distance is designed between the adjacent floating gates. Wherein, the substrate, the multiple floating gates, and the gate electrode are separated by a plurality of active regions.

### BACKGROUND OF THE INVENTION

1. Field of the Inventions

The present invention relates to a transistor, and more particular to a transistor having multiple floating gates and fabrication method thereof

2. Description of Related Art

In recent years, with the increasing importance of energy issues, the development of power electronics and power devices has become one of the key technologies. The tradeoff of how to get good sustaining voltage ability and a conduction resistance and reducing fabrication costs are research focus of power devices. Although many studies have published to use a few masks to complete the fabrication process, it is still a special process that requires wire bonding technology to connect the power device with main circuit. Therefore, it is still limited on the cost reduction and application flexibility.

When the power device which roles as a switch is turned off, the voltage sustaining ability must be higher than an external bias voltage to protect the internal circuit from being damage by the external bias voltage. The application range could be from ten volts to several thousand volts. No matter the applied voltage level, to let the power device has no voltage drop when it is turned on and decrease power loss to a minimum value, an area occupied by single power device is often much larger than the main circuit. Therefore, the overall chip area cannot be effectively reduced. When the conduction resistance is smaller, it means that the voltage drop and the power consumption are lower, which can effectively improve the function of chip and lower the power consumption.

The general power device often uses P/N junction to design the voltage sustaining ability and the conduction resistance (On-resistance, RON). However, with the change in concentration of voltage sustaining area to increase the voltage sustaining ability, the conduction resistance will also increase with several times, and this phenomenon is called the silicon limit, which means the voltage sustaining and conduction property fabricated by the silicon substrate are limited by the silicon limit.

### SUMMARY OF THE INVENTION

The present invention provides a transistor, comprising: a substrate; a gate electrode forming on the substrate; and multiple floating gates formed on the substrate, and a fixed distance forms between each floating gate; wherein, the substrate, the multiple floating gates, and the gate electrode are separated by a plurality of active regions.

The present invention provides a fabrication method for a transistor, comprising: defining a device operation area on the substrate; defining a device sustaining voltage area at the device operation area by a mask; depositing a junction layer, a high dielectric constant material layer, and a hard mask layer; depositing a silicon nitride layer and etching back to form a plurality of sidewall space layers to define a drain region; forming a plurality of active regions; and etching the hard mask layer and depositing an N-type metal.

### BRIEF DESCRIPTION OF THE DRAWINGS

The patent or application file contains at least one color drawing. Copies of this patent or patent application publication with color drawing will be provided by the USPTO upon request and payment of the necessary fee.

FIG. 1 is a schematic diagram of a transistor according to an embodiment of the present invention;

FIG. 2(a) to FIG. 2(c) is a simulation diagram for the characteristic of a conventional N-type metal oxide semiconductor field effect transistor and a measurement diagram for a N-type metal oxide semiconductor field effect transistor by 28 nm fabrication process;

FIG. 3(a) is an ID-VD relationship diagram of a transistor according to an embodiment of the present invention;

FIG. 3(b) is the characterized conduction resistance of a transistor calculated by combining with FIG. 3(a) according to an embodiment the present invention;

FIG. 3(c) is an electric potential distribution diagram of a transistor according to an embodiment of the present invention;

FIG. 3(d) is a breakdown voltage characteristic diagram of a transistor according to an embodiment the present invention;

FIG. 4(a) is a schematic diagram of breakdown position for the gate of a conventional N-type MOS transistor;

FIG. 4(b) and FIG. 4(c) is schematic diagram of a transistor having three e floating gates according to an embodiment of the present invention;

FIG. 5 is a comparison diagram of the surface electric field for a transistor with different number of floating gates according to an embodiment of the present invention;

FIG. 6(a) to FIG. 6(g) is a fabrication process diagram of a transistor having multiple floating gates according to an embodiment of the present invention; and

FIG. 7 is a fabrication flow chart of a transistor having multiple floating gates according to an embodiment of the present invention.

### DETAILED DESCRIPTION OF THE PREFERRED EMBODIMENT

The following content combines with the drawings and the embodiment for describing the present invention in detail.

FIG. 1 is a schematic diagram of a transistor according to an embodiment of the present invention. As shown in FIG. 1, a transistor 10 regard an active region (for example, N+ region) 12 as a field limitation ring, and floating gates FG1˜FG3 can be regarded as a field plate so that the transistor 10 may also be called as a floating field plate metal oxide semiconductor field effect transistor. Through the floating gates FG1˜FG3, it effectively divides the drain voltage of the transistor 10 so as to reduce the maximum electric field and breakdown effect caused by a gate electrode 16, and to increase the breakdown voltage. In one embodiment, a substrate 14 (for example, P-well), the floating gates FG1˜FG3, and the gate electrode 16 are all separated by the active region (e.g., N+ region 12).

The present invention utilizes three floating gates FG1˜FG3 as an example, but the present invention is not limited thereto. For illustrating conveniently, in one embodiment, a length of the gate electrode 16 of the transistor 10 is LG; the space between the adjacent floating gates FG1˜FG3 is 90 nm; a length of each floating gate FG1˜FG3 is 40 nm; a distance between the gate electrode 16 and the floating gate FG1˜FG3 is 90 nm; the widths of the gate electrode 16 and the floating gates FG1˜FG3 are all 120 nm.

When the device is operated in an off-state, providing a positive voltage at the drain, and when the current at the drain reaches 1×10−5 ampere, it is defined as the breakdown. The drain voltage at this time is called the breakdown voltage.

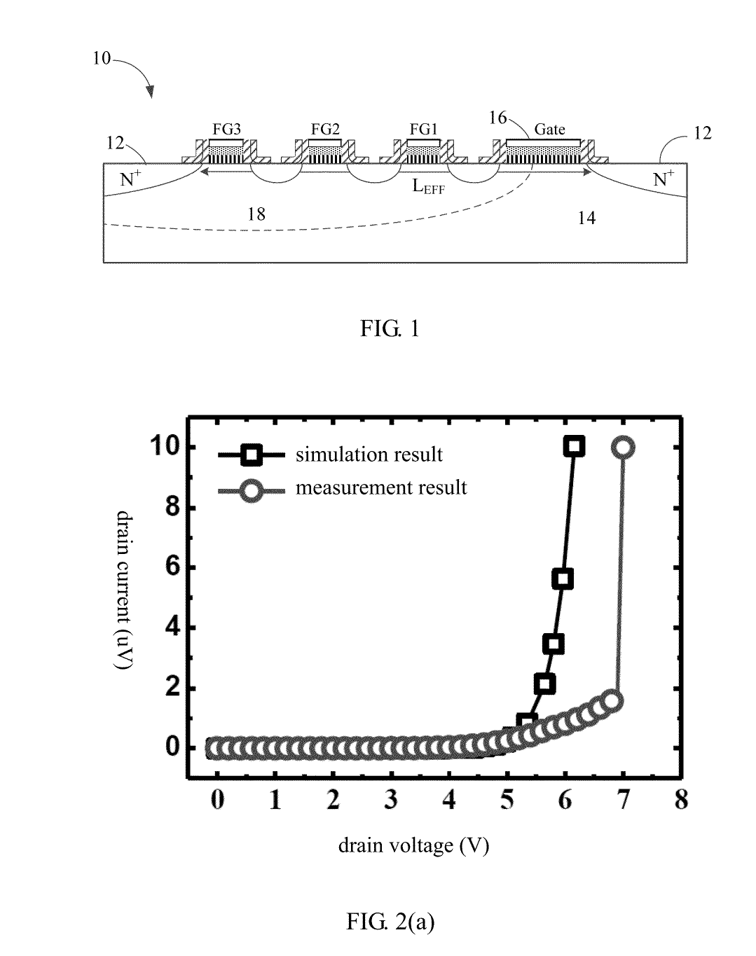

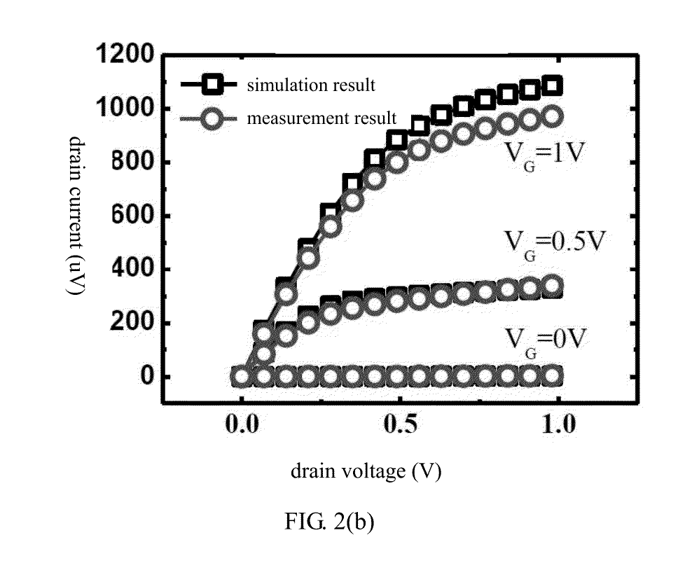

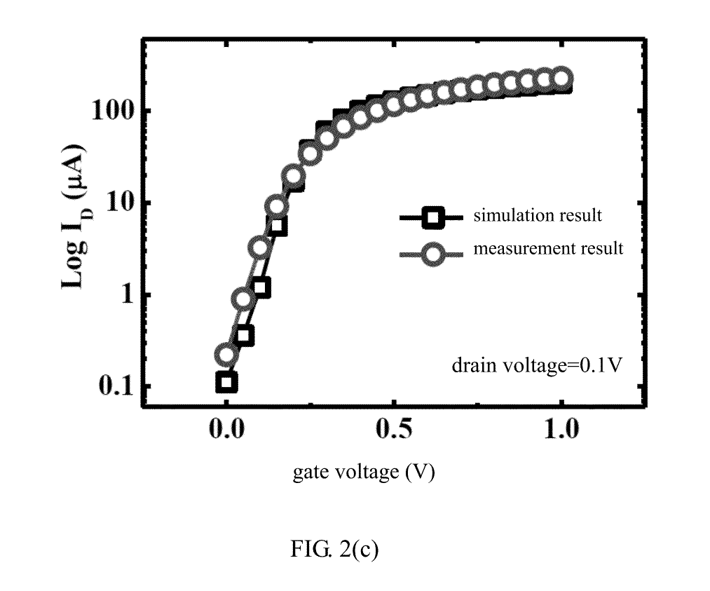

FIG. 2 (a)˜FIG. 2 (c) is a simulation diagram for the characteristic of a conventional N-type metal oxide semiconductor field effect transistor and a measurement diagram for a N-type metal oxide semiconductor field effect transistor by 28 nm fabrication process. FIG. 2 (a) is comparison diagram of breakdown characteristic of simulation and measurement when the gate length of the transistor is 90 nm. FIG. 2 (b) and FIG. 2 (c) are respectively comparison diagrams of ID-VD characteristic of simulation and measurement.

With reference to FIG. 1, when the drain voltage of the transistor 10 is increased, through the capacitive coupling induction at an overlapping area of the floating gate FG1˜FG3 and the N+ region 12, it extends a boundary of a depletion region 18 and also reduces the concentration of the electric field such that it provides more electric potential to sustain under the floating gates FG1˜FG3 so that the voltage are relatively increased. Therefore, for different number of the floating gates, as the number of floating gates is increased, the electric potential can be effectively transmitted so that the distribution of the electric potential is smoother. This structure can significantly improve the breakdown caused by the gate electrode 16 so as to increase the breakdown voltage of the transistor 10.

When the device is operated in an on-state, providing a low voltage at the drain and an operation voltage at the gate electrode, the characterized conduction resistance R_{ON,SP} at this time is given by equation (1):

RONSP=VDID×Area (1)

Wherein, the Area is the equivalent channel length LEFF multiplied by the device width (Area=LEFF×WCell). While the equivalent channel length LEFF is different according to the number of the floating gates, as shown below;

| The number of the floating gates | Equivalent channel length LEFF |
|---|---|
| 0 | 90 nm |
| 1 | 220 nm |
| 3 | 480 nm |
| 6 | 870 nm |
| 9 | 1260 nm |

In one embodiment, the gate voltage V_{G} is 1V and the drain voltage V_{D} is 0.1V. The conduction principle of the floating field plate metal oxide semiconductor field effect transistor is that the drain voltage V_{D} utilizes the capacitive coupling to induce the voltage of floating gates so as to conduct N-type channels under the floating gates FG1˜FG3. Therefore, when using two drain voltage V_{D} (for example, 1V and 3.3V), the calculated resistance is a characterized conduction resistance. The following will explain the influence of the different number of the floating gates to the conduction characteristic of the transistor 10.

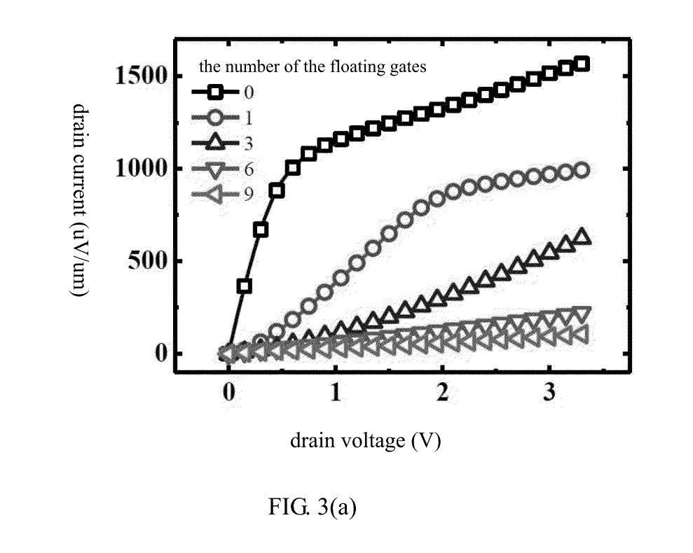

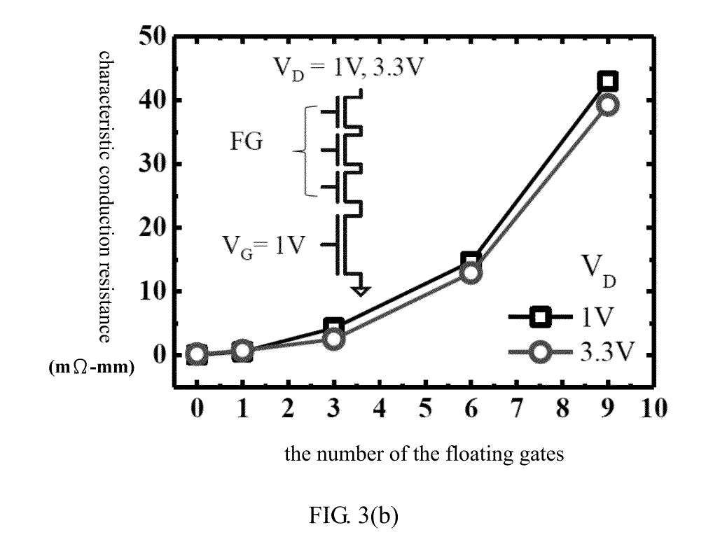

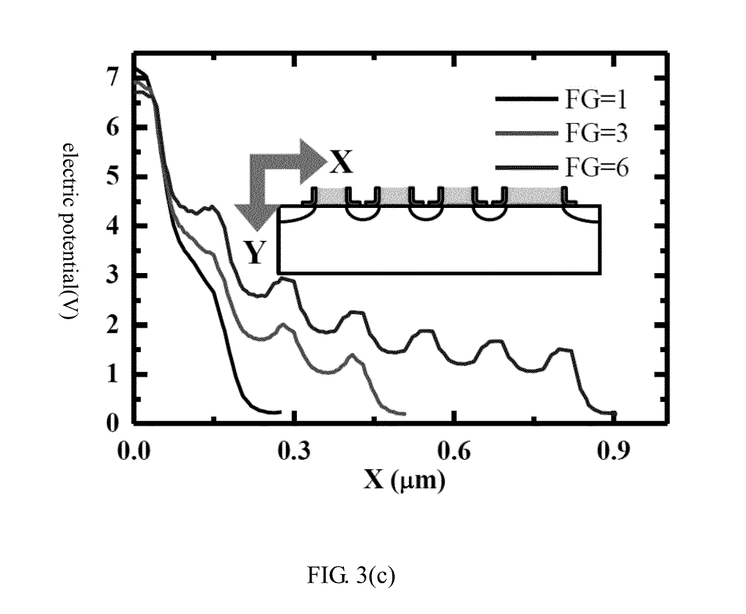

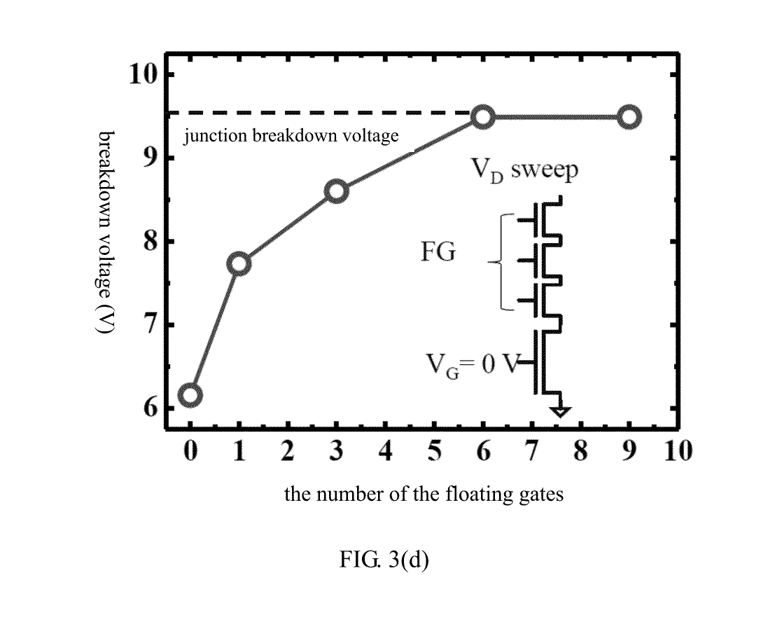

FIG. 3(a) is an ID-VD relationship diagram of a transistor according to an embodiment of the present invention. It will describe further by combining FIG. 3 with FIG. 1. When the gate voltage V_{G} is 1V, from FIG. 3, it can find that the conduction current (the drain current) of the transistor will decrease as the number of the floating gates is increased. FIG. 3(b) is characterized conduction resistance of the transistor calculated by combining with FIG. 3(a) according to an embodiment the present invention. When the drain voltage V_{D} is 1V, and when the number of the floating gates is also increased, the characterized conduction resistance is also increased. That is because as the number of the floating gates is increased, the coupling induction voltage of the floating gates closed to the gate electrode 16 is decreased so that the inversion layer is not easily to produce. Therefore, the channel resistance RCh is increased and the whole conduction resistance is also increased.

As shown in FIG. 3(b), when the drain voltage VD is 3.3V and the number of floating gates is 3, the characterized conduction resistance is reduced about 40.7%; when the number of floating gates is 6, the characterized conduction resistance is reduced about 12.2%; when the number of floating gates is 9, the characterized conduction resistance is reduced about 8.6%. When the number of floating gates is 0 or 1, there is no significant change in the characterized conduction resistance. However, in fact, when the drain voltage VD is increased from 1V to 3.3V, from FIG. 3(b), it can find that the working area is from the linear region into the saturation region, so that the characterized conduction resistance is increased, but it is still smaller than the characterized conduction resistance when the number of the floating gates is from 3 to 9.

In one embodiment, the transistor 10 utilizing the N+ region 12 and the floating gates FG1˜FG3 as the field limitation ring and field plate can effective transmit divided voltage and the drain potential so as to mitigate the breakdown caused by the gate electrode because of the electric field concentration. Using the number of floating gates respectively as 1, 3, and 6 for example, FIG. 3(c) is an electric potential distribution diagram of a transistor according to of an embodiment of the present invention. As shown in FIG. 3(c), along the direction of X axis, for the distribution of the voltage drop, it is more even as the number of floating gates is increased. FIG. 3(d) is a breakdown voltage characteristic diagram of a transistor according to an embodiment the present invention. As shown in FIG. 3(d), when the number of floating gates is increased from 0 to 9, the breakdown voltage also increases from 6.15V to 9.49V. In addition, when the number of the floating gates increased from 6 to 9, the sustaining voltage is not increased correspondingly. The main reason is the change of breakdown mechanism. When the number of floating gates reaches 6, as the increasing of the drain voltage VD, it will not affect by the gate electrode to cause early breakdown and become N+/P-well junction breakdown. Therefore, when the number of the floating gates is increased to 9, it has reached the limitation value of the breakdown voltage, and the breakdown voltage is not significantly increased.

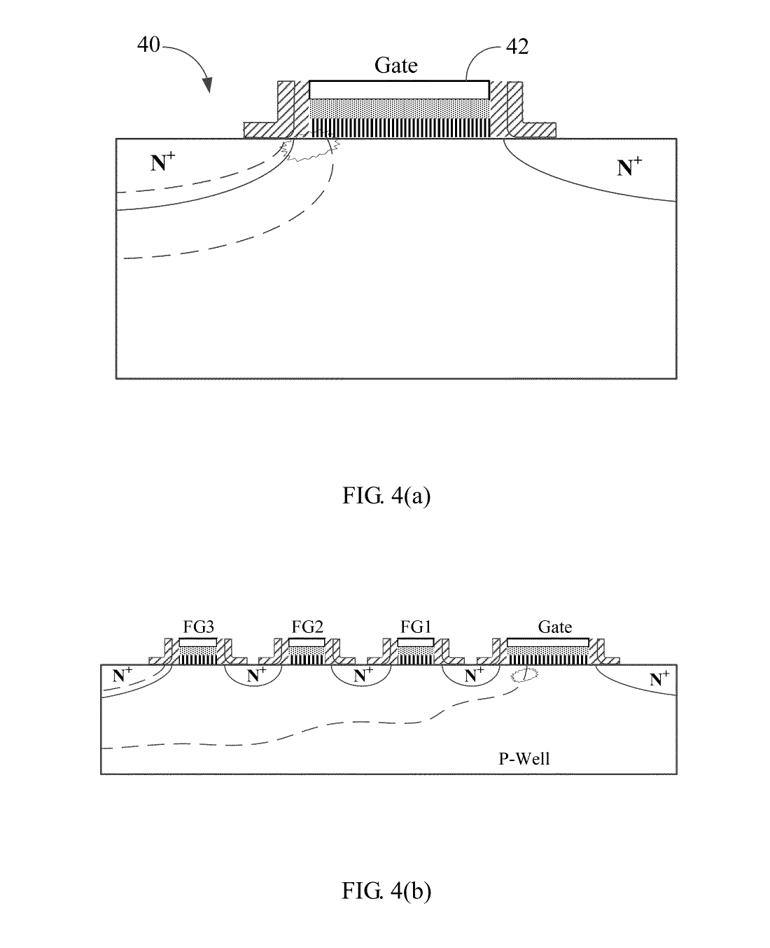

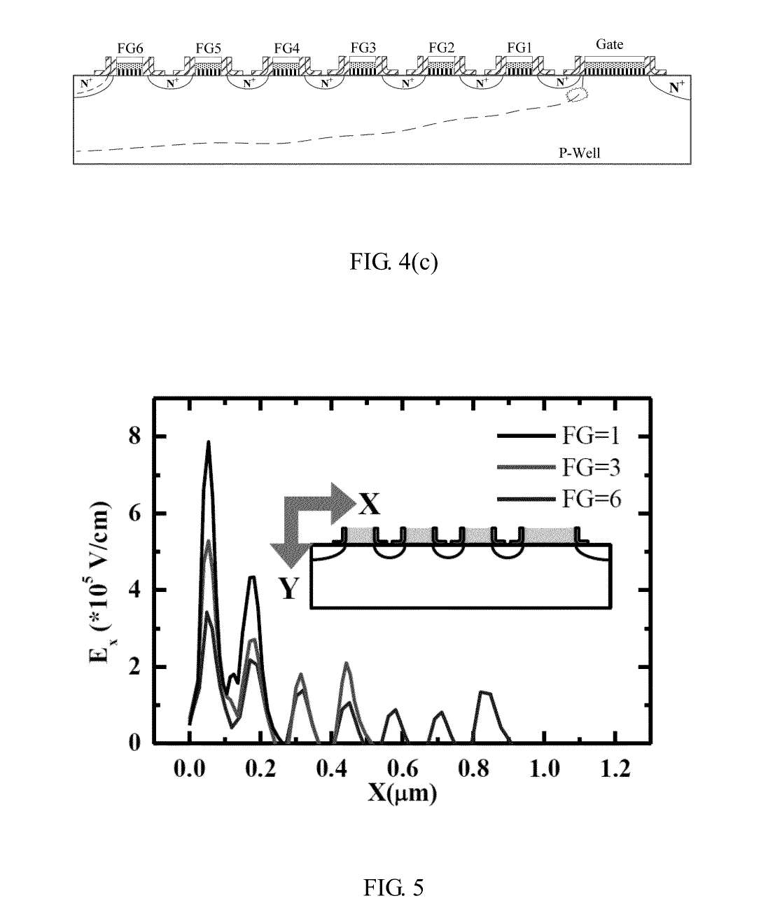

FIG. 4(a) is a schematic diagram of breakdown position for the gate of a conventional N-type MOS transistor. A gate electrode 42 of a transistor 40 will be affected by the gate voltage V_{G} so as to breakdown early on the surface. Specially, when the device is shrinking, the equivalent oxide layer is also decreased. In 28 nm logic fabrication process, the equivalent oxide layer is only about 1 nm, and therefore, the affection of the surface by the gate voltage V_{G} is more obvious. Therefore, it will firstly produce the band to band tunneling effect at the gate electrode 42 to cause early breakdown. FIG. 4(b) and FIG. 4(c) is schematic diagram of a transistor having three floating gates according to an embodiment of the present invention. As shown in FIG. 4(b) and FIG. 4(c), as the number of the floating gates is increased, the hot spot will transfer from the boundary surface of the depletion region to underneath of the depletion region so as to become the N+/P-well junction breakdown; The thing of the hot spot transferring from the boundary surface of the depletion region to underneath of the depletion region also represents the surface high electric field applied on the gate dielectric layer will also be reduced so as to improve the reliability of the gate dielectric layer. With the number of the floating gates increasing, the breakdown point is gradually away from the surface to form the junction breakdown so that the gate dielectric layer is less affected by the high electric field, and the breakdown characteristic can be appeared repeatedly without change due to the destroy of the interface.

FIG. 5 is a comparison diagram of surface electric field for a transistor with different number of floating gates according to an embodiment of the present invention. As shown in FIG. 5, the surface electric field will reduce with the increase of the number of the floating gates so as to meet design expectation.

Although the transistor having multiple floating gates according to one embodiment of the present invention extends the boundary of the depletion region so as to mitigate the electric field concentration effect, improve the breakdown caused by the gate electrode, and increase the sustaining voltage. However, the characteristic conduction resistance cause inversion layer because of insufficient capacitive coupling induction voltage of the floating gates. Therefore, the drain voltage has to be applied a higher potential on it such that capacitive coupling induction voltage of the floating gates can form a N-type channel with higher concentration and the channel resistance is decreased correspondingly.

The breakdown voltage of a common N-type MOS transistor is 6.15V. The breakdown voltage of a transistor having one floating gate is 7.73V, which increase about 25.7%. The breakdown voltage of a transistor having three floating gates is 8.6V, which increase about 39.8%. The breakdown voltage of a transistor having six or nine floating gates is 9.49V, which increase about 54.3%. Through the above formula and the list of the equivalent channel length LEFF, when the drain voltage VD is 1V, it can obtain:

RON,SP(NMOS)=0.87 kΩ*μm×0.09 μm=0.08 mΩ·mm2;

RON,SP(FG1)=2.6 kΩ*μm×0.22 μm=0.57 mΩ·mm2;

RON,SP(FG3)=8.91 kΩ*μm×0.48 μm=4.28 mΩ·mm2;

RON,SP(FG6)=16.91 kΩ*μm×0.87 μm=14.71 mΩ·mm2;

RON,SP(FG9)=34.12 kΩ*μm×1.26 μm=42.99 mΩ·mm2;

The characteristic conduction resistance of a transistor having one floating gate increases 6.12 times comparing to a common N-type metal oxide semiconductor field effect transistor. The characteristic conduction resistance of a transistor having three floating gates increases 52.5 times. The characteristic conduction resistance of a transistor having six and nine floating gates respectively increases 182.9 times and 536.4 times. It can obtain that increasing the number of floating gates from 6 to 9 only increases the characteristic conduction resistance as 1.92 times, but the breakdown voltage cannot be increased because of reaching the junction limit of the breakdown voltage. In summary, if it designs the breakdown voltage to approach N+/P-well junction breakdown, the range of the characteristic conduction resistance must be between 5 to 10 mΩ-mm2. Therefore, it should control the number of floating gates to be between 3 to 6. Once the number of the floating gates is over six, it will only increase the conduction resistance of the device, but its breakdown voltage does not change.

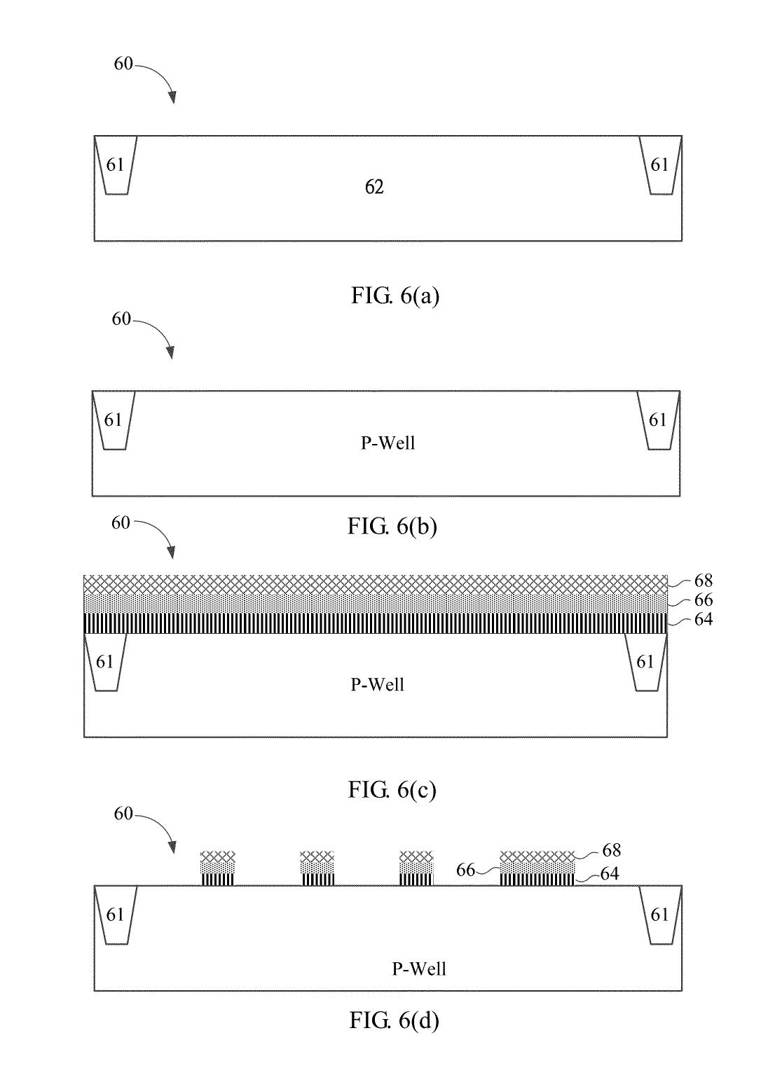

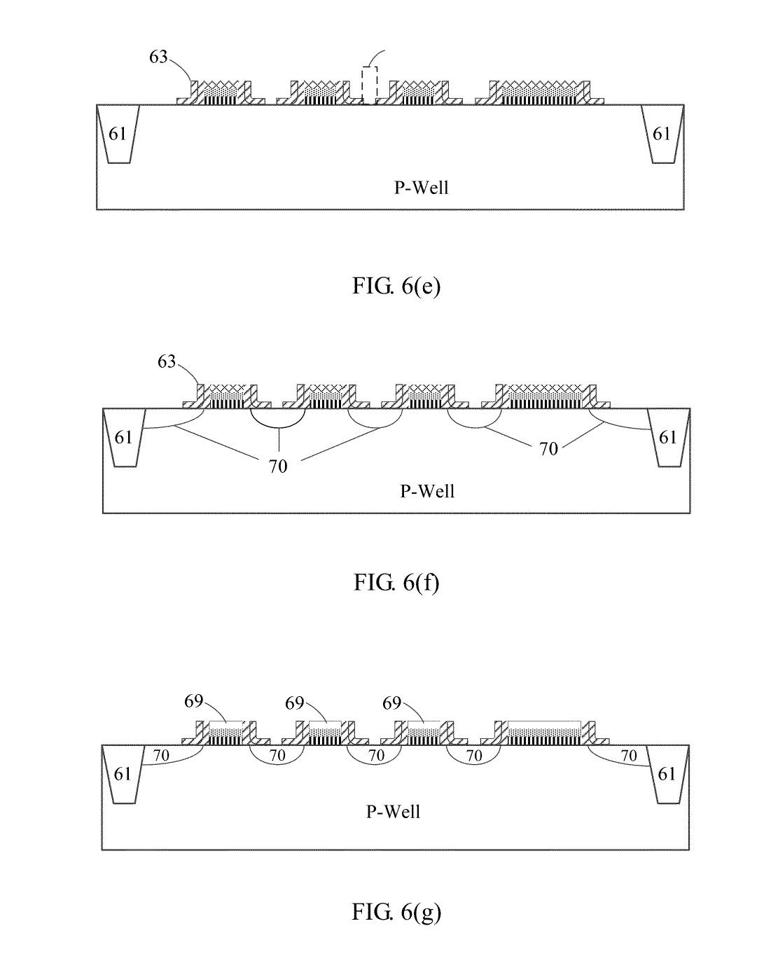

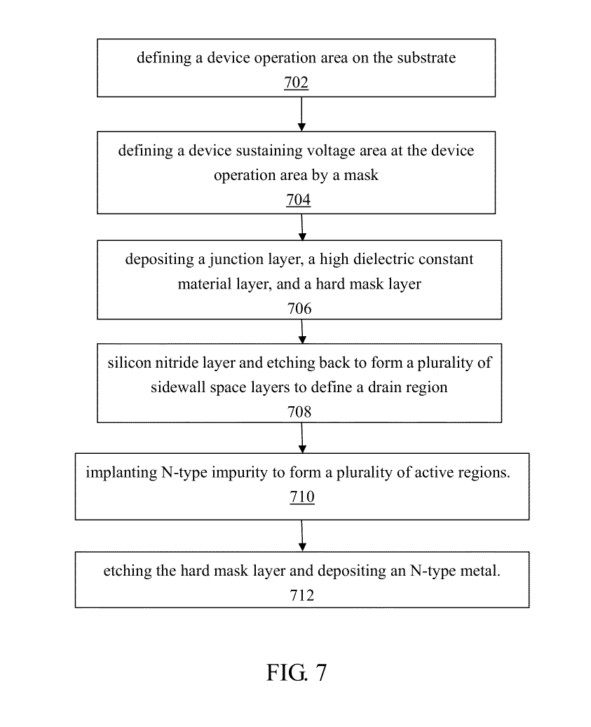

FIG. 6(a) to FIG. 6(g) is a fabrication process diagram of a transistor having multiple floating gates according to an embodiment of the present invention. FIG. 7 is a fabrication flow chart of a transistor having multiple floating gates according to an embodiment of the present invention. The following will combine FIG. 7 with FIG. 6(a) to FIG. 6(g) for illustrating. In one embodiment, a transistor having multiple floating gates can be integrated into the complementary metal oxide semiconductor logic fabrication process and it does not require any additional mask to complete.

In step 702, it defines a device operation area on a substrate of a transistor structure 60. As shown in FIG. 6(a), in one embodiment, it utilizes the shallow trench isolation (STI) technology on a P-type substrate (not shown). It uses shallow trenches 61 to define a device operation area 62 between two shallow trenches 61.

In step 704, it defines a device sustaining voltage area by a mask. As shown in FIG. 6(b), in one embodiment, it uses a P-type well mask to dope a P-well for defining the device operation area 62 as the device sustaining voltage area, that is, the P-well.

In step 706, it deposits a junction layer (for example, silicon dioxide SiO2) and a high dielectric constant material layer (for example, HfO2) on the surface of the device operation area. And it deposits a hard mask layer on surface of the high dielectric constant material layer. As shown in FIG. 6(c), in one embodiment, the surface of the P-well is deposited with a junction layer 64, and then, it deposits a high dielectric constant material layer 66 on the surface of the junction layer 64. Finally, it forms a hard mask layer 68 on the surface of the high dielectric constant material layer 66. Subsequently, it utilizes etching to remove a portion of the junction layer 64, a portion of the high dielectric constant material layer 66, and a portion of the hard mask layer 68, as shown in FIG. 6(d).

In step 708, it deposits silicon nitride on the surface of the P-well. In one embodiment, as shown in FIG. 6(e), the silicon nitride covers the surface of the P-well and a portion of the junction layer 64, a portion of the high dielectric constant material layer 66, and a portion of the hard mask layer 68. Then, it etches back the silicon nitride so as to form a plurality of sidewall space layers 63 in order to define a drain region 65.

In step 710, it implants N-type impurity to form a plurality of active regions. In one embodiment, as shown in FIG. 6(f), implanting the N-type ion into the surface of the P-well, the surface of the P-well which are not masked by the sidewall space layers 63 forms a plurality of active regions (e.g., N+)70.

In step 712, it etches the hard mask layer and deposits an N-type metal. In one embodiment, as shown in FIG. 6(g), it etches the hard mask layer 68 and deposits an N-type metal 69 on the high dielectric constant material layer 66. Wherein, the P-well, the floating gates and the gate electrode are all separated by the N+ active region, which significantly decreases the conduction resistance.

The embodiment of the invention provides a transistor, and through depositing multiple floating gates, it can effectively improve the breakdown caused by the gate electrode such that the voltage approaches junction breakdown. Therefore, the device does not require the drift region mask and additional wire bonding technology. It can reduce the fabrication costs and increase the flexibility range of the high-voltage circuit design.

The above embodiments of the present invention are not used to limit the claims of this invention. Any use of the content in the specification or in the drawings of the present invention which produces equivalent structures or equivalent processes, or directly or indirectly used in other related technical fields is still covered by the claims in the present invention.

What is claimed is:

1. A transistor, comprising:
a substrate;
a gate electrode forming on the substrate; and
multiple floating gates formed on the substrate, and a fixed distance forms between each floating gate;
wherein, the substrate, the multiple floating gates, and the gate electrode are separated by a plurality of active regions.

2. The transistor according to claim 1, wherein, the active regions are N+regions.

3. The transistor according to claim 1, wherein, the substrate is a P-well.

4. The transistor according to claim 1, wherein, the number of the floating gates ranges from 3 to 6.

5. A fabrication method for a transistor, comprising:
defining a device operation area on the substrate;
defining a device sustaining voltage area at the device operation area by a mask;
depositing a junction layer, a high dielectric constant material layer, and a hard mask layer;
depositing a silicon nitride layer and etching back to form a plurality of sidewall space layers to define a drain region;
forming a plurality of active regions; and
etching the hard mask layer and depositing an N-type metal.

6. The method according to claim 5, further comprising:
utilizing a shallow trench isolation technology to define the device operation area.

7. The method according to claim 5, wherein, the mask is a P-well mask.

8. The method according to claim 5, wherein, the junction layer is a silicon dioxide layer.

9. The method according to claim 5, wherein, in the step of forming a plurality of active regions comprises a step of implanting N-type impurity to form the plurality of active regions.

10. The method according to claim 9, wherein, the plurality of active regions are N+ regions.
